(19) United States
(12) Patent Application Publication
(10) Pub. No.: US 2025/0365932 A1
(43) Pub. Date: Nov. 27, 2025

(54) SEMICONDUCTOR DEVICES

(71) Applicant: Samsung Electronics Co., Ltd., Suwon-si (KR)

(72) Inventors: Soyeon Kim, Suwon-si (KR); Suklae Kim, Suwon-si (KR); Yeram Kim, Suwon-si (KR); Sungsoo Yim, Suwon-si (KR)

(21) Appl. No.: 18/922,658

(22) Filed: Oct. 22, 2024

(30) Foreign Application Priority Data
May 21, 2024 (KR) 10-2024-0065947

(51) Int. Cl. H10B 12/00

(52) U.S. Cl. CPC H10B 12/315; H10B 12/0335; H10B 12/05

(57) ABSTRACT

A semiconductor device may include a bit line extending in a first direction, a gate structure including a gate electrode on the bit line extending in a second direction perpendicular to the first direction and a gate insulation pattern on a sidewall of the gate electrode in the first direction, a channel on the bit line, the channel extending in a third direction perpendicular to a plane defined by the first and second directions on a sidewall of the gate structure in the first direction, a landing pad on the channel; and a capacitor on the landing pad, wherein the capacitor has a lowermost surface lower than an upper surface of the landing pad where an upper surface of the bit line provides a base reference plane.

### CROSS-REFERENCE TO RELATED APPLICATION

This application claims priority under 35 U.S.C. § 119 to Korean Patent Application No. 10-2024-0065947, filed May 21, 2024, in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a memory device including a capacitor.

### BACKGROUND

A capacitor in a DRAM device includes a lower electrode, a dielectric layer and an upper electrode sequentially stacked. As integration of semiconductor devices increases, an aspect ratio of the lower electrode increases, which may make the manufacturing process more difficult.

### SUMMARY

Example embodiments provide a semiconductor device having improved characteristics.

According to example embodiments, there is provided a semiconductor device. The semiconductor device may include a bit line extending in a first direction, a gate structure including a gate electrode on the bit line extending in a second direction perpendicular to the first direction and a gate insulation pattern on a sidewall of the gate electrode in the first direction, a channel on the bit line, the channel extending in a third direction perpendicular to a plan defined by the first and second directions on a sidewall of the gate structure in the first direction, a landing pad on the channel; and a capacitor on the landing pad, wherein the capacitor has a lowermost surface lower than an upper surface of the landing pad where an upper surface of the bit line provides a base reference plane.

According to example embodiments, there is provided a semiconductor device. The semiconductor device may include a bit line extending in a first direction, a channel on the bit line, a contact plug on the channel, a landing pad on the contact plug and a capacitor including a lower capacitor electrode on the landing pad a dielectric pattern on a sidewall and an upper surface of the lower capacitor electrode and an upper capacitor electrode on a surface of the dielectric pattern, wherein the dielectric pattern has a lowermost surface lower than a lower surface of the lower capacitor electrode where an upper surface of the bit line provides a base reference plane, and wherein sidewalls of the contact plug, the landing pad and the lower capacitor electrode are aligned with each other in a direction substantially perpendicular to the upper surface of the bit line.

According to example embodiments, there is provided a semiconductor device. The semiconductor device may include a plurality of bit lines each extending in a first direction, the plurality of bit lines being spaced apart from each other in a second direction crossing the first direction, a plurality of channels spaced apart from each other in the first direction on each of the plurality of bit lines, each of the plurality of channels extending in a third direction substantially perpendicular to an upper surface of each of the plurality of bit lines, a gate structure including a gate insulation pattern on each of opposite sidewalls in the first direction of one of the plurality of channels and a gate electrode on a sidewall in the first direction of the gate insulation pattern, a contact plug on the one of the plurality of channels, a landing pad on the contact plug and a capacitor including a lower capacitor electrode on the landing pad, a dielectric pattern on a sidewall and an upper surface of the lower capacitor electrode and an upper capacitor electrode on a surface of the dielectric pattern, wherein the capacitor has a lowermost surface lower than an upper surface of the landing pad where an upper surface of one of the plurality of bit lines corresponding to the one of the plurality of channels provides a base reference plane.

The semiconductor device in accordance with example embodiments may include the landing pad between the contact plug on the channel and the lower capacitor electrode included in the capacitor, and the dielectric pattern included in the capacitor may be formed not only on a sidewall of the lower capacitor electrode but also on a portion of a sidewall of the landing pad. Thus, a portion of the landing pad may also serve as the lower capacitor electrode of the capacitor, thereby increasing an effective area of the capacitor and thus a capacitance of the capacitor may increase.

### BRIEF DESCRIPTION OF THE DRAWINGS

FIGS. 1 and 2 are a plan view and a cross-sectional view, respectively, illustrating a semiconductor device in accordance with example embodiments.

FIGS. 3 to 17 are plan views and cross-sectional views illustrating a method of manufacturing a semiconductor device in accordance with example embodiments.

### DETAILED DESCRIPTION

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. In example embodiments, the first and second directions D1 and D2 may be orthogonal to each other.

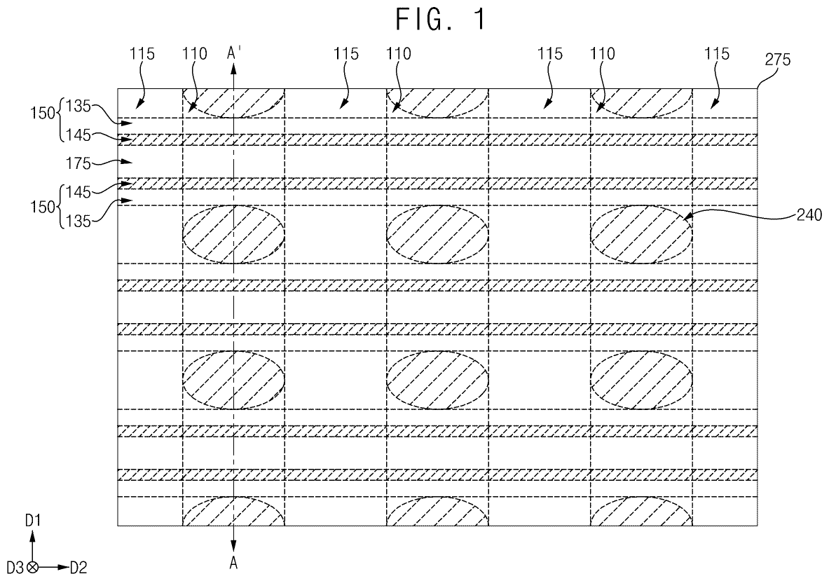

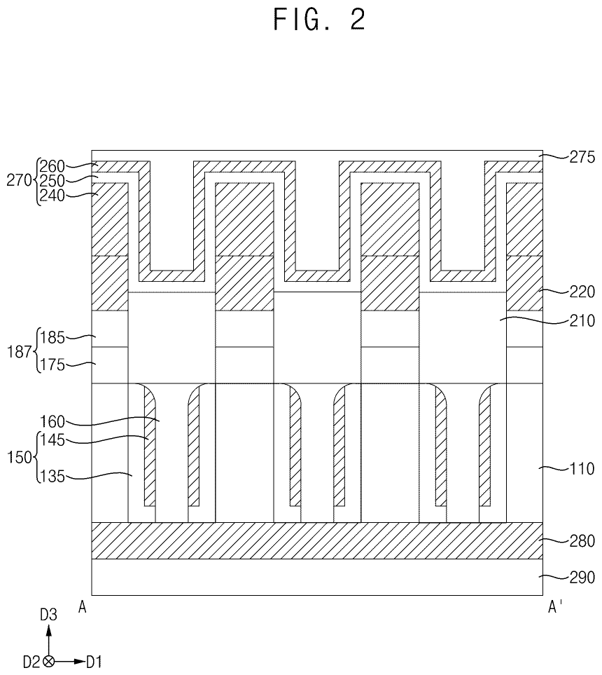

FIGS. 1 and 2 are a plan view and a cross-sectional view, respectively, illustrating a semiconductor device in accordance with example embodiments. Specifically, FIG. 2 is a cross-sectional view taken along line A-A′ of FIG. 1.

Referring to FIGS. 1 and 2, the semiconductor device may include a bit line 280, a mold 115, a gate structure 150, a channel 110, a contact plug 187, a landing pad 220, a capacitor 270 and a plate electrode 275.

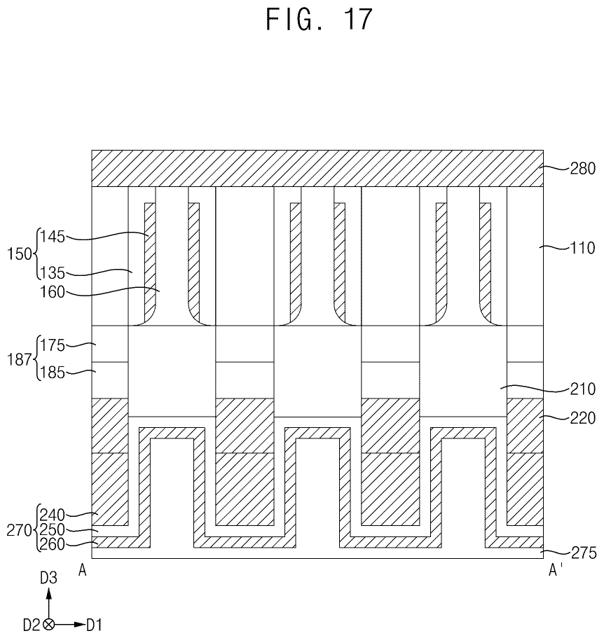

The semiconductor device may further include first and second insulation patterns 160 and 210, a second insulating interlayer 285 (refer to FIG. 16) and a third insulating interlayer 290.

Referring to FIGS. 1 and 2 together with FIGS. 16 and 17, the bit line 280 may extend in the first direction D1 on the third insulating interlayer 290 and a plurality of bit lines 280 may be spaced apart from each other in the second direction D2.

Additionally, the second insulating interlayer 285 may extend in the first direction D1 between the bit lines 280 neighboring in the second direction D2 on the third insulating interlayer 290.

In example embodiments, the bit line 280 may include a conductive material, e.g., a metal, a metal nitride or a metal silicide, and each of the second and third insulating interlayers 285 and 290 may include an oxide, e.g., silicon oxide.

The first insulation pattern 160 may be disposed on the bit line 280 and the second insulating interlayer 285, may contact upper surfaces of the bit line 280 and the second insulating interlayer 285, and may extend in the second direction D2. The first insulation pattern 160 may include an insulating material, e.g., silicon oxide, silicon nitride, etc., and in some embodiments, the first insulation pattern 160 may include a void therein, which may include, e.g., air.

The gate structure 150 may extend in the second direction D2 on the bit line 280 and the second insulating interlayer 285, and may be disposed on each of opposite sidewalls of the first insulation pattern 160 in the first direction D1. The gate structure 150 may include a gate electrode 145 and a gate insulation pattern 135 sequentially stacked on each of the opposite sidewalls of the first insulation pattern 160 in the first direction D1. In example embodiments, the gate structure 150 may have a symmetrical shape in the first direction D1 with respect to the first insulation pattern 160.

In example embodiments, an inner sidewall of the gate electrode 145 in the first direction D1 may contact a sidewall of the first insulation pattern 160 in the first direction D1, and an outer sidewall of the gate electrode 145 in the first direction D1 may contact an inner sidewall of the gate insulation pattern 135 in the first direction D1. In example embodiments, the first insulation pattern 160 may be on and at least partially cover an upper surface of the gate electrode 145, and the gate insulation pattern 135 may be on and at least partially cover a lower surface of the gate electrode 145.

The gate insulation pattern 135 may include a horizontal portion, which may include a lower surface contacting upper surfaces of the bit line 280 and the second insulating interlayer 285 and an upper surface contacting the lower surface of the gate electrode 145, and a vertical portion, which may be disposed on the horizontal portion of the gate insulation pattern 135 and have an outer sidewall contacting sidewalls of the channel 110 and the mold 115 in the first direction D1. Thus, a cross-section of the gate insulation pattern 135 in the second direction D2 may have an “L” shape.

The gate electrode 145 may include a metal, e.g., molybdenum (Mo), ruthenium (Ru), tungsten (W), etc., and the gate insulation pattern 135 may include an oxide, e.g., silicon oxide, aluminum oxide, etc.

The mold 115 may be disposed on the second insulating interlayer 285, and may contact an upper surface of the second insulating interlayer 285. The mold 115 may contact respective sidewalls of the gate structures 150 neighboring in the first direction D1.

In example embodiments, a plurality of molds 115 may be spaced apart from each other in the first direction D1 by the gate structure 150 and the first insulation pattern 160 on the second insulating interlayer 285. The mold 115 may be disposed between channels 110 neighboring in the second direction D2 and may contact the respective sidewalls of the channels 110 in the second direction D2.

The mold 115 may include an insulating material, e.g., silicon nitride.

The channel 110 may contact an upper surface of the bit line 280 and the sidewall of each of the gate structures 150 neighboring in the first direction D1. In example embodiments, an upper surface of the channel 110 may be substantially coplanar with an upper surface of the gate structure 150, and a lower surface of the channel 110 may be substantially coplanar with a lower surface of the gate structure 150.

In example embodiments, a plurality of channels 110 may be spaced apart from each other in the first direction D1 by the gate structure 150 and the first insulation pattern 160 on each of the bit lines 280. The channel 110 and the mold 115 may be alternately and repeatedly disposed in the second direction D2.

In example embodiments, the channel 110 may include a semiconductor material, e.g., silicon (Si), germanium (Ge), silicon-germanium (Si—Ge), etc. In other embodiments, the channel 110 may be include one or more oxide semiconductor materials, e.g., zinc tin oxide (ZTO), indium zinc oxide (IZO), zinc oxide (ZnOx), indium gallium zinc oxide (IGZO), indium gallium silicon oxide (IGSO), indium oxide (InOx, In₂O₃), SnO₂ (tin oxide), titanium oxide (TiOₓ), zinc oxide nitride (ZnxOyNz), magnesium zinc oxide (MgxZnyOz), indium zinc oxide (InxZnyOa), indium gallium zinc oxide (InxGayZnzOa), zirconium indium zinc oxide (ZrxInyZnzOa), hafnium indium zinc oxide (HfxInyZnzOa), tin indium zinc oxide (SnxInyZnzOa), aluminum tin indium zinc oxide (AlxSnyInzZnaOd), silicon indiumzinc oxide (SixInyZnzOa), zinc tin oxide (ZnxSnyOz), aluminum zinc tin oxide (AlxZnySnzOa), gallium zinc tin oxide (GaxZnySnzOa), zirconium zinc tin oxide (ZrxZnySnzOa), and/or indium gallium silicon oxide (InGaSiO).

The contact plug 187 may be disposed on the channel 110, and may contact the upper surface of the channel 110. In an example embodiment, the contact plug 187 may also contact portions of the mold 115 and the gate insulation pattern 135 adjacent to the channel 110. However, the contact plug 187 may not contact an upper surface of the gate electrode 145. As shown in FIG. 2, a width in the first direction D1 of a lower surface of the contact plug 187 is substantially the same as a width in the first direction D1 of the channel 110, however, the embodiments of the inventive concept may not be limited thereto.

In example embodiments, a plurality of contact plugs 187 may be spaced apart from each other in the first and second directions D1 and D2. The contact plug 187 may include a first contact pattern 175 and a second contact pattern 185 sequentially stacked in the third direction D3.

The first contact pattern 175 may include, e.g., undoped polysilicon, and the second contact pattern 185 may include, e.g., polysilicon doped with impurities.

The landing pad 220 may be disposed on the contact plug 187 and may contact an upper surface of the contact plug 187. In example embodiments, a plurality of landing pads 220 may be spaced apart from each other in the first and second directions D1 and D2 corresponding to the plurality of contact plugs 187, and may be arranged in a lattice shape or a honeycomb shape in a plan view. The landing pad 220 may have a shape of, e.g., a circle, an ellipse, a polygon, a polygon with rounded corners, etc., in a plan view.

In example embodiments, the landing pad 220 may include a metal, e.g., titanium, tantalum, etc., a metal nitride, e.g., titanium nitride, tantalum nitride, etc., or a conductive material, e.g., a metal silicide.

The second insulation pattern 210 may be disposed on the gate structure 150, the first insulation pattern 160 and the mold 115. In example embodiments, the second insulation pattern 210 may include first and second extension portions, which may extend in the first and second directions D1 and D2, respectively, and may intersect each other. The second insulation pattern 210 may be on and at least partially cover opposite sidewalls of each of the plurality of contact plugs 187 in the first and second directions DI and D2, and may be on and at least partially cover lower portions of opposite sidewalls of the landing pad 220 in the first and second directions D1 and D2. Thus, an upper surface of the second insulation pattern 210 may be higher than or coplanar with the upper surface of the contact plug 187, and may be lower than an upper surface of the landing pad 220 as shown in FIG. 2.

In an embodiment, a sidewall of the second insulation pattern 210 in the first direction D1 may be aligned with the sidewall in the first direction D1 of the gate structure 150 in the third direction D3, but embodiments of the inventive concept may not be limited thereto.

The second insulation pattern 210 may include an insulating nitride, e.g., silicon nitride.

The capacitor 270 may include lower and upper capacitor electrodes 240 and 260, and a dielectric pattern 250 disposed between the lower and upper capacitor electrodes 240 and 260. In example embodiments, the lower capacitor electrode 240 may contact the upper surface of the landing pad 220 and may at least partially overlap the landing pad 220 and the contact plug 187 in the third direction D3. In an embodiment, sidewalls of the lower capacitor electrode 240, the landing pad 220 and the contact plug 187 may be aligned with each other in the third direction D3.

The dielectric pattern 250 may be disposed on an upper surface and a sidewall of the lower capacitor electrode 240, an upper sidewall of the landing pad 220 and the upper surface of the second insulation pattern 210, and the upper capacitor electrode 260 may be disposed on the dielectric pattern 250.

As the plurality of landing pads 220 are spaced apart from each other in the first and second directions D1 and D2, a plurality of lower capacitor electrodes 240 may also be spaced apart from each other in the first and second directions D1 and D2.

In example embodiments, the lower capacitor electrode 240 may have a shape of, e.g., a circle, an ellipse, a polygon, a polygon with rounded corners, etc., in a plan view. The lower capacitor electrodes 240 may be arranged in a lattice pattern or a honeycomb pattern in a plan view.

Each of the lower and upper capacitor electrodes 240 and 260 may include a metal, e.g., titanium, tantalum, etc., a metal nitride, e.g., titanium nitride, tantalum nitride, etc., or a metal silicide, and the dielectric pattern 250 may include, e.g., a metal oxide.

In an embodiment, the lower capacitor electrode 240 and the landing pad 220 may include different materials, and thus the lower capacitor electrode 240 and the landing pad 220 may be distinguished from each other. In another embodiment, the lower capacitor electrode 240 and the landing pad 220 may include a same material, and thus the lower capacitor electrode 240 and the landing pad 220 may be merged with each other to form an integral or monolithic structure.

The plate electrode 275 may be disposed on the upper capacitor electrode 260 and may include, e.g., silicon-germanium, that is undoped or doped with impurities.

In the semiconductor device, current may flow in the third direction D3, that is, in the vertical direction, within the channel 110 between the bit line 280 and the landing pad 220, and thus the semiconductor device may include a vertical channel transistor (VCT), which may have a vertical channel.

In example embodiments, the upper surface of the second insulation pattern 210 on and at least partially covering the sidewall of the landing pad 220 may be lower than the upper surface of the landing pad 220, and the dielectric pattern 250 disposed on the second insulation pattern 210 may contact not only the sidewall of the lower capacitor electrode 240, but also the upper sidewall of the landing pad 220 which may not be covered by the second insulation pattern 210 or have the second insulation pattern 210 disposed thereon. Because the landing pad 220 includes a conductive material as the lower capacitor electrode 240, the upper portion of the landing pad 220 whose sidewall is covered by the dielectric pattern 250 may serve as the lower capacitor electrode 240.

Thus, in the capacitor 270 in accordance with example embodiments, the dielectric pattern 250 between the lower capacitor electrode 240 and the landing pad 220 and the upper capacitor electrode 260 may have an increased effective area, and the capacitor 270 including the dielectric pattern 250 may have an increased capacitance. Thus, the semiconductor device may have improved electrical characteristics.

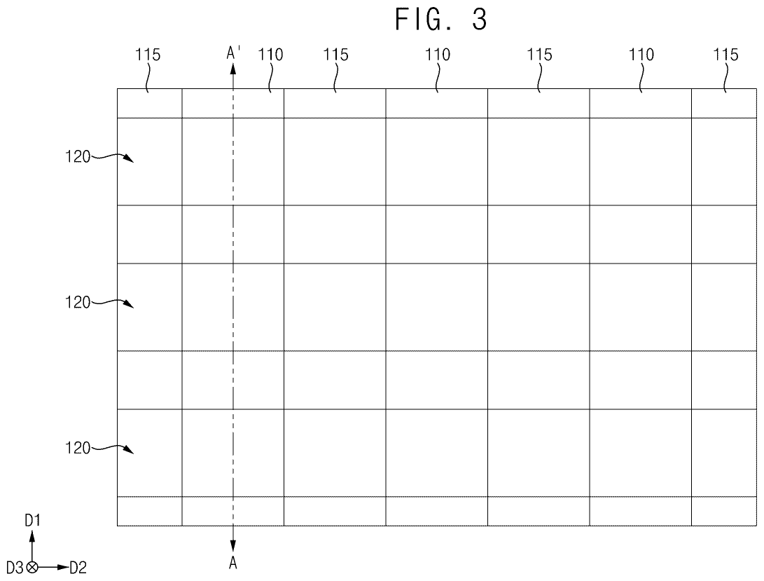

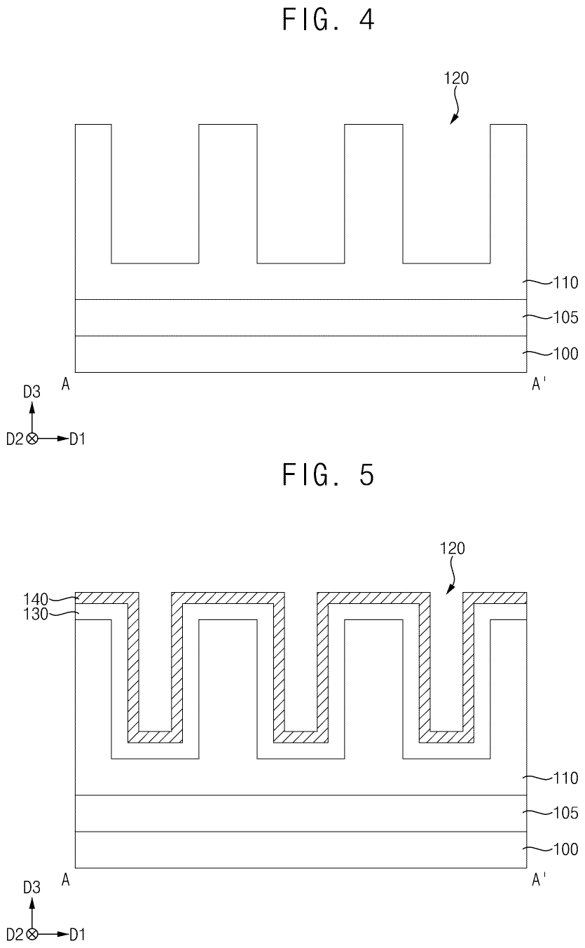

FIGS. 3 to 17 are plan views and cross-sectional views illustrating a method of manufacturing a semiconductor device in accordance with example embodiments. Specifically, FIGS. 3, 7 and 16 are the plan views, and FIGS. 4-6, 8-15 and 17 are cross-sectional views taken along lines A-A′ of corresponding plan views, respectively.

Referring to FIGS. 3 and 4, a first insulating interlayer 105 and a channel layer may be sequentially formed on a substrate 100, and an etching process may be performed on the channel layer to form a first opening at least partially exposing an upper surface of the first insulating interlayer 105.

In example embodiments, the first opening may extend in the first direction D1 and a plurality of first openings may be spaced apart from each other in the second direction D2.

A deposition process may be performed to form a mold layer on the first insulating interlayer 105 and the channel layer to at least partially fill the first opening, and a planarization process may be performed on the mold layer until an upper surface of the channel layer is at least partially exposed, so that the mold layer may be formed on the first insulating interlayer 105 to extend in the first direction D1. The planarization process may include, e.g., a chemical mechanical polishing (CMP) process and/or an etch back process.

In example embodiments, a plurality of mold layers may be spaced apart from each other in the second direction D2, and thus, the mold layer and the channel layer may be alternately and repeatedly formed in the second direction D2.

An etching process may be performed on upper portions of the mold layer and the channel layer to form a first trench 120. In example embodiments, the first trench 120 may extend in the second direction D2 and a plurality of first trenches 120 may be spaced apart from each other in the first direction D1.

As the first trench 120 is formed, the mold layer and the channel layer may be transformed into a mold 115 and a channel 110, respectively. Hereinafter, in each of the channel 110 and the mold 115, a portion extending in the first direction D1 below the first trench 120 may be referred to as a lower portion, and a portion between the first trenches 120 disposed in the first direction D1 may be referred to as an upper portion.

Referring to FIG. 5, a gate insulation layer 130 and a gate electrode layer 140 may be sequentially stacked on the channel 110 and the mold 115.

In example embodiments, each of the gate insulation layer 130 and the gate electrode layer 140 may be formed by a deposition process, e.g., a chemical vapor deposition (CVD) process, an atomic layer deposition (ALD) process, etc. In an example embodiment, the deposition processes may be performed in-situ.

The first trench 120 may not be completely filled by the gate insulation layer 130 and the gate electrode layer 140 and a portion of the first trench 120 may remain, however a width in the first direction D1 of the remaining portion of the first trench 120 may be decreased from the initial first trench 120.

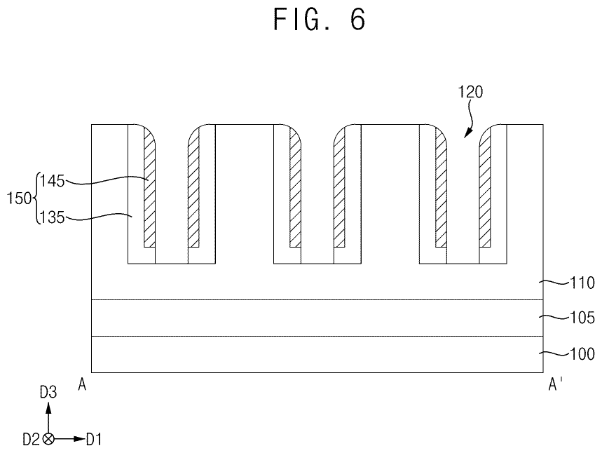

Referring to FIG. 6, an anisotropic etching process may be performed on the gate insulation layer 130 and the gate electrode layer 140, and thus, the gate insulation layer 130 and the gate electrode layer 140 may transformed into a gate insulation pattern 135 and a gate electrode 145, respectively.

In example embodiments, each of the gate insulation pattern 135 and the gate electrode 145 may be formed on each of opposite sidewalls in the first direction D1 of each of the channel 110 and the mold 115, and may extend in the second direction D2. As the anisotropic etching process is performed, a central bottom of the first trench 120 may be exposed.

The gate insulation pattern 135 and the gate electrode 145 may collectively form a gate structure 150.

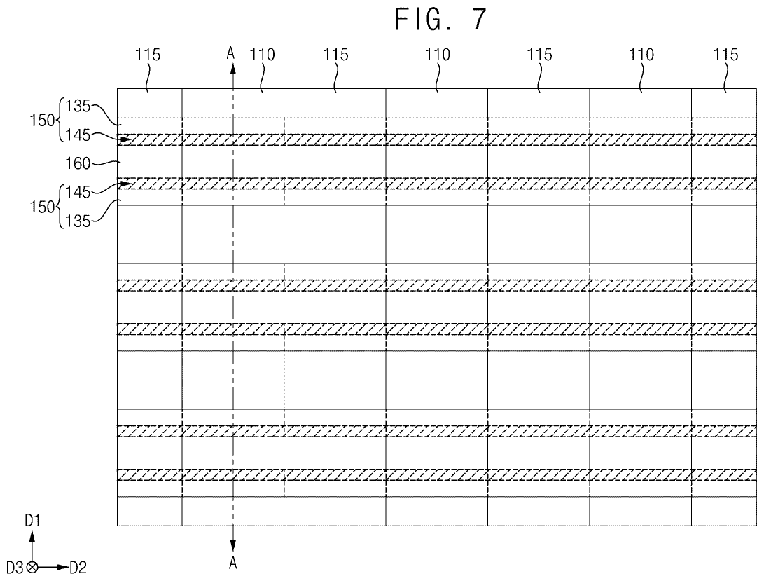

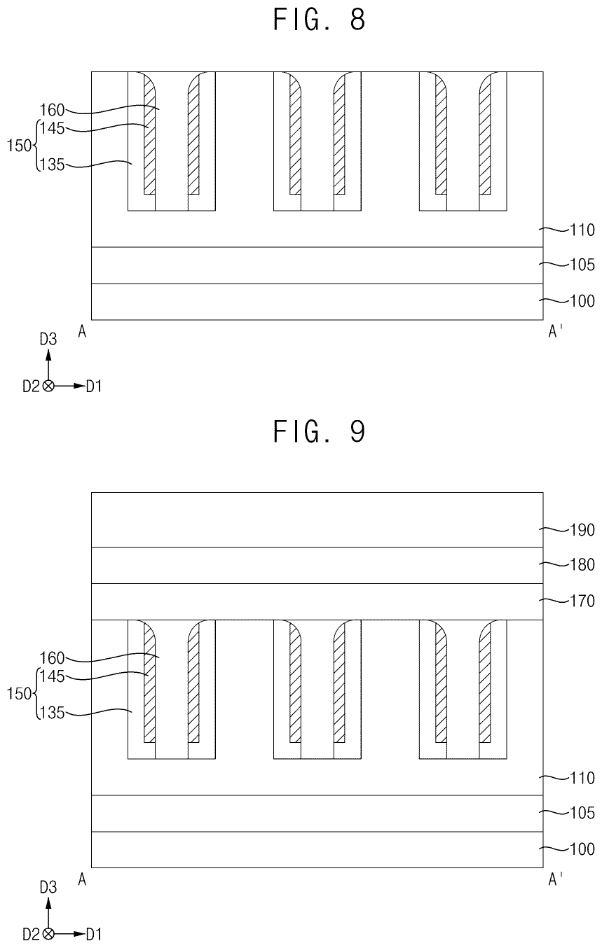

Referring to FIGS. 7 and 8, a first insulation layer may be formed on the channel 110 and the mold 115 to at least partially fill the first trench 120, and a planarization process may be performed on the first insulation layer to form a first insulation pattern 160.

The planarization process may include, e.g., a chemical mechanical polishing (CMP) process and/or an etch back process.

In example embodiments, the first insulation pattern 160 may contact a sidewall of the gate electrode 145 in the first direction D1, and may extend in the second direction D2.

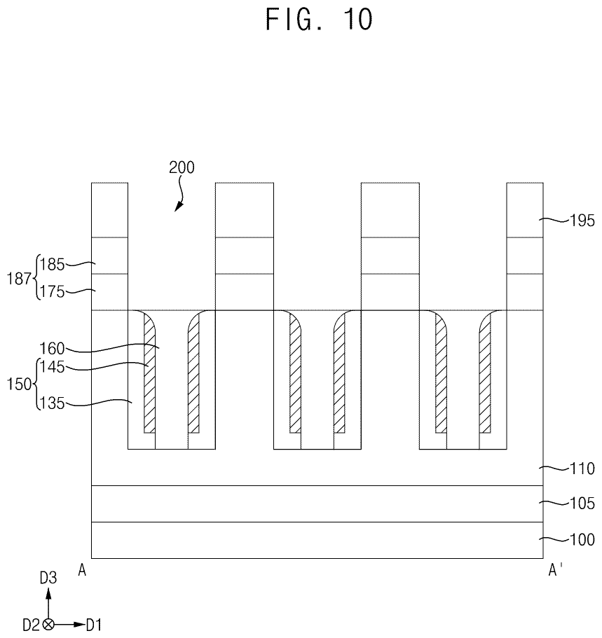

Referring to FIG. 9, a first contact layer 170, a second contact layer 180 and a sacrificial layer 190 may be sequentially stacked on the channel 110, the mold 115, gate structure 150 and the first insulation pattern 160.

In example embodiments, each of the first contact layer 170, the second contact layer 180 and the sacrificial layer 190 may be formed by a deposition process, e.g., a chemical vapor deposition (CVD) process, an atomic layer deposition (ALD) process, etc. In an example embodiment, the deposition processes may be performed in-situ. The sacrificial layer 190 may include, e.g., a silicon oxide.

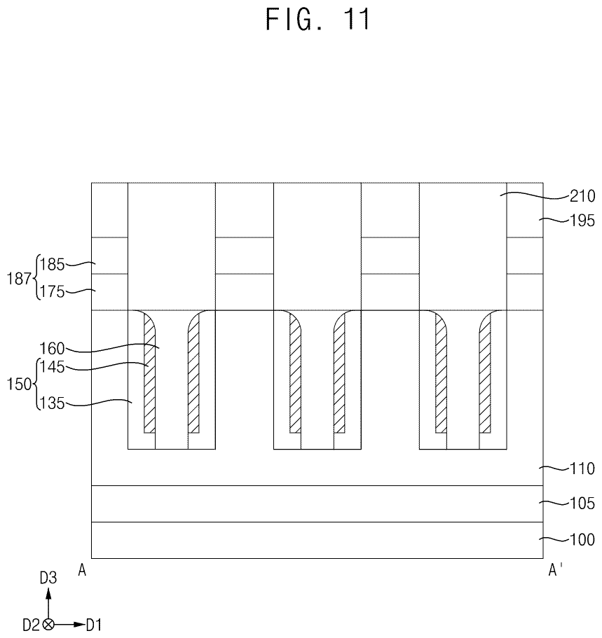

Referring to FIG. 10, a planarization process may be performed on the first contact layer 170, the second contact layer 180 and the sacrificial layer 190 to form a second opening 200 at least partially exposing upper surfaces of the mold 115, gate structure 150 and the first insulation pattern 160.

Thus, the first contact layer 170, the second contact layer 180 and the sacrificial layer 190 may be transformed into a first contact pattern 175, a second contact pattern 185 and a sacrificial pattern 195, respectively. The first contact pattern 175 and the second contact pattern 185 may collectively form a contact plug 187.

In example embodiments, a plurality of contact plugs 187 may be spaced apart from each other in the first and second directions D1 and D2, and may contact upper surfaces of upper portions of corresponding ones of the channels 110, respectively. Additionally, a plurality of sacrificial patterns 195 may be spaced apart from each other in the first and second directions D1 and D2, and may contact upper surfaces of upper portions of corresponding ones of the channels 110, respectively. FIG. 10 shows that a width in the first direction D1 of a lower surface of each of the contact plugs 187 is substantially the same as a width in the first direction D1 of the upper portion of the corresponding one of the channels 110, however embodiments of the inventive concept may not be limited thereto. That is, in some embodiments, the width in the first direction D1 of the lower surface of each of the contact plugs 187 may be less than the width in the first direction D1 of the upper portion of the corresponding one of the channels 110, and thus the upper portion of the channel 110 may be partially exposed by the second opening 200.

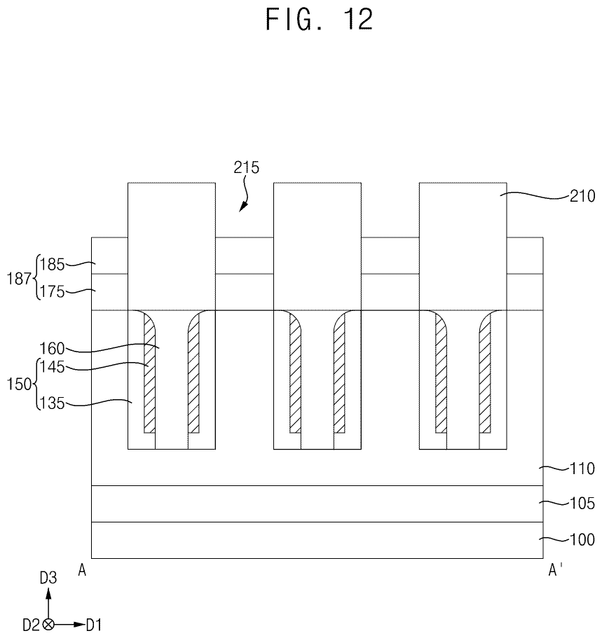

Referring to FIG. 11, a second insulation layer may be formed on the mold 115, the gate structure 150, and the first insulation pattern 160 to at least partially fill the second opening 200, and a planarization process may be performed on the second insulation layer to form a second insulation pattern 210.

The planarization process may include, e.g., a chemical mechanical polishing (CMP) process and/or an etch back process.

In example embodiments, the second insulation pattern 210 may include first and second extension portions, which may extend in the first and second directions D1 and D2, respectively, and may intersect each other. The second insulation pattern 210 may be on and at least partially cover opposite sidewalls in the first and second directions D1 and D2 of each of the contact plug 187 and the sacrificial pattern 195.

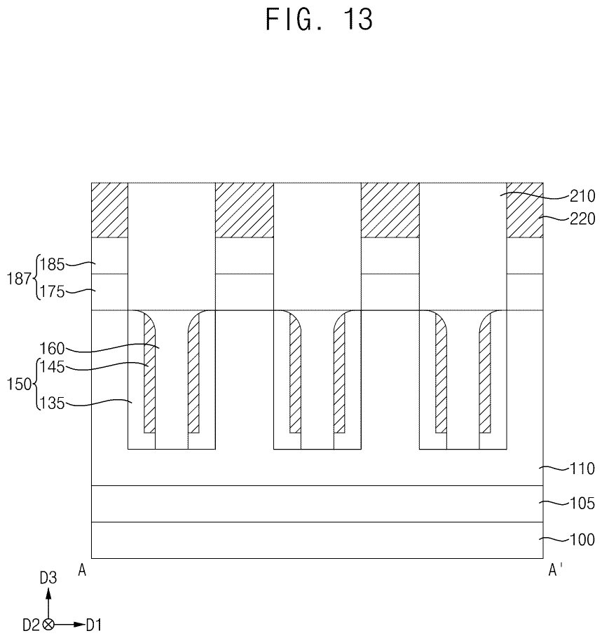

Referring to FIG. 12, the sacrificial pattern 195 may be removed by an etching process to form a third opening 215, and thus an upper surface of the contact plug 187 and sidewalls in the first and second directions D1 and D2 of the second insulation pattern 210 may be exposed.

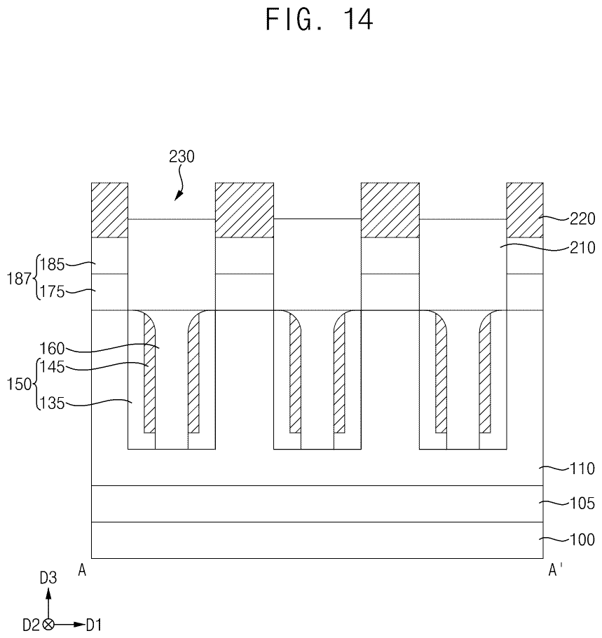

Referring to FIG. 13, a landing pad layer may be formed on the contact plug 187 and the second insulation pattern 210, and a planarization process may be performed on the landing pad layer until an upper surface of the second insulation pattern 210 is at least partially exposed to form a landing pad 220.

In example embodiments, a plurality of landing pads 220 may be spaced apart from each other in the first and second directions D1 and D2, and each of the landing pads 220 may contact the upper surface of a corresponding one of the contact plugs 187.

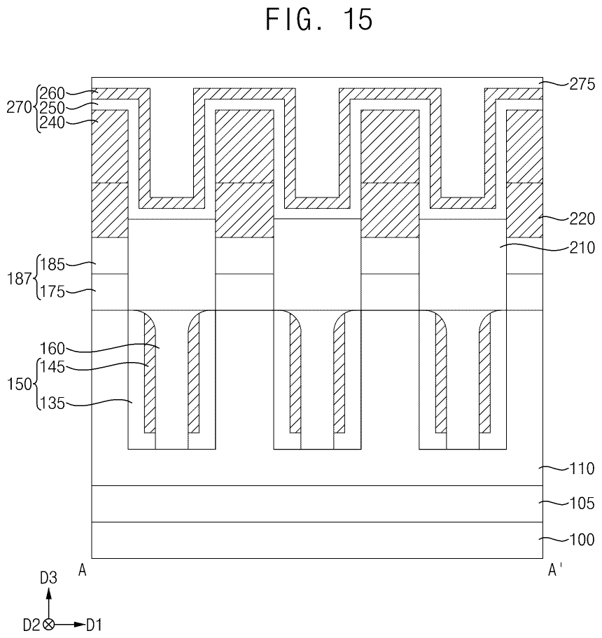

Referring to FIG. 14, an upper portion of the second insulation pattern 210 may be removed by an etching process to form a fourth opening 230 at least partially exposing upper sidewalls in the first and second directions D1 and D2 of the landing pad 220

Thus, an upper surface of the second insulation pattern 210 may be lower than an upper surface of the landing pad 220 and higher than or coplanar with an upper surface of the second contact pattern 185 as shown in FIG. 14. In example embodiments, the etching process may include, e.g., a wet etching process.

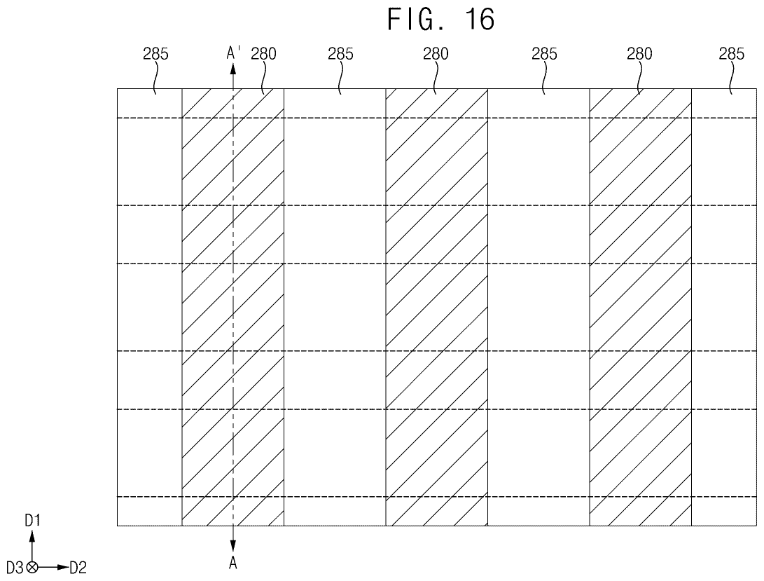

Referring to FIG. 15, a lower capacitor electrode 240 may be formed to contact the upper surface of the landing pad 220, a dielectric pattern 250 may be formed on an upper surface and a sidewall of the lower capacitor electrode 240, the upper sidewall of the landing pad 220 and the upper surface of the second insulation pattern 210, and an upper capacitor electrode 260 may be formed on the dielectric pattern 250.

The lower capacitor electrode 240, the dielectric pattern 250 and the upper capacitor electrode 260 may collectively form a capacitor 270. In example embodiments, a plurality of lower capacitor electrodes 240 may be spaced apart from each other in the first and second directions D1 and D2 to contact the upper surfaces of corresponding ones of the landing pads 220.

A plate electrode 275 may be formed on the capacitor 270. The plate electrode may include, e.g., a silicon germanium that is undoped or doped with impurities.

As illustrated above, the upper portion of the second insulation pattern 210 may be removed by an etching process to at least partially expose the upper sidewall of the landing pad 220, so that the dielectric pattern 250 formed on the upper surface and the sidewall of the lower capacitor electrode 240 may also be formed on the upper sidewall of the landing pad 220. Thus, not only the lower capacitor electrode 240, but also the upper portion of the landing pad 220 may serve as the lower capacitor electrode 240 of the capacitor 270.

Referring to FIGS. 16 and 17, the substrate 100 may be flipped so that various structures on the substrate 100 may be flipped upside down, and hereinafter, are described based on the changed direction. That is, for example, the upper portion and the lower portion of each of the channel 110 and the mold 115 may be referred to as a lower portion and an upper portion, respectively, of each of the channel 110 and the mold 115.

In example embodiments, for example, a grinding process may be performed on the substrate 100, the first insulating interlayer 105, and the upper portions of the channel 110 and the mold 115 until upper surfaces of the first insulation pattern 160 and the gate structure 150 are at least partially exposed. Thus, the upper portion of each of the channel 110 and the mold 115 may be removed, while the lower portion of each of the channel 110 and the mold 115 may remain. In example embodiments, a plurality of channels 110 may be spaced apart from each other in the first and second direction D1 and D2, and a plurality of molds 115 may be spaced apart from each other in the first and second direction D1 and D2.

A second insulating interlayer 285 may be formed on the channel 110, the mold 115, the gate structure 150 and the first insulation pattern 160, the second insulating interlayer 285 may be partially removed to form a conductive layer contacting the upper surface of the channel 110, and a planarization process may be performed on the conductive layer until an upper surface of the second insulating interlayer 285 is at least partially exposed to form a bit line 280.

In example embodiments, the bit line 280 may extend in the first direction DI and a plurality of bit lines 280 may be spaced apart from each other in the second direction D2.

Referring back to FIGS. 1 and 2, a third insulating interlayer 290 may be formed on the bit line 280 and the second insulating interlayer 285, and the substrate 100 may be flipped to complete the fabrication of the semiconductor device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a bit line extending in a first direction;
a gate structure including:
a gate electrode on the bit line extending in a second direction perpendicular to the first direction; and
a gate insulation pattern on a sidewall of the gate electrode in the first direction;
a channel on the bit line, the channel extending in a third direction perpendicular to a plane defined by the first and second directions on a sidewall of the gate structure in the first direction;
a landing pad on the channel; and
a capacitor on the landing pad,
wherein the capacitor has a lowermost surface lower than an upper surface of the landing pad where an upper surface of the bit line provides a base reference plane.

2. The semiconductor device according to claim 1, wherein the capacitor includes:
a lower capacitor electrode on the upper surface of the landing pad;
a dielectric pattern on a sidewall and an upper surface of the lower capacitor electrode; and
an upper capacitor electrode on a surface of the dielectric pattern,
wherein the dielectric pattern has a lowermost surface lower than a lowermost surface of the lower capacitor electrode where the upper surface of the bit line provides the base reference plane.

3. The semiconductor device according to claim 2, further comprising a contact plug contacting an upper surface of the channel and a lower surface of the landing pad.

4. The semiconductor device according to claim 3, wherein the lowermost surface of the dielectric pattern is substantially coplanar with a lower surface of the contact plug.

5. The semiconductor device according to claim 3, wherein sidewalls of the lower capacitor electrode, the landing pad and the contact plug are aligned with each other in the third direction.

6. The semiconductor device according to claim 3, wherein the contact plug includes a first contact pattern and a second contact pattern sequentially stacked in the third direction, and
wherein the first contact pattern includes undoped silicon and the second contact pattern includes doped silicon.

7. The semiconductor device according to claim 2, wherein the lower capacitor electrode and the landing pad include a same metal.

8. The semiconductor device according to claim 2, wherein the lower capacitor electrode and the landing pad include different metals from each other.

9. The semiconductor device according to claim 1, wherein the gate insulation pattern is on a lower surface of the gate electrode.

10. The semiconductor device according to claim 9, wherein the sidewall of the gate electrode is a first sidewall of the gate electrode, the semiconductor device further comprising an insulation pattern on the bit line, the insulation pattern on a second sidewall of the gate electrode in the first direction, and
wherein the insulation pattern is on an upper surface of the gate electrode and a lower sidewall of the gate insulation pattern.

11. A semiconductor device comprising:
a bit line extending in a first direction;
a channel on the bit line;
a contact plug on the channel;
a landing pad on the contact plug; and
a capacitor including:
a lower capacitor electrode on the landing pad;
a dielectric pattern on a sidewall and an upper surface of the lower capacitor electrode; and
an upper capacitor electrode on a surface of the dielectric pattern,
wherein the dielectric pattern has a lowermost surface lower than a lower surface of the lower capacitor electrode where an upper surface of the bit line provides a base reference plane, and
wherein sidewalls of the contact plug, the landing pad and the lower capacitor electrode are aligned with each other in a direction substantially perpendicular to the upper surface of the bit line.

12. The semiconductor device according to claim 11, wherein a lowermost surface of the dielectric pattern is substantially coplanar with a lower surface of the contact plug.

13. The semiconductor device according to claim 11, wherein the contact plug includes a first contact pattern and a second contact pattern sequentially stacked in the direction substantially perpendicular to the upper surface of the bit line, and
wherein the first contact pattern includes undoped silicon, and the second contact pattern includes doped silicon.

14. The semiconductor device according to claim 11, wherein the lower capacitor electrode and the landing pad include a same metal.

15. The semiconductor device of claim 11, wherein the lower capacitor electrode and the landing pad include different metals from each other.

16. A semiconductor device comprising:
a plurality of bit lines each extending in a first direction, the plurality of bit lines being spaced apart from each other in a second direction crossing the first direction;
a plurality of channels spaced apart from each other in the first direction on each of the plurality of bit lines, each of the plurality of channels extending in a third direction substantially perpendicular to an upper surface of each of the plurality of bit lines;
a gate structure including:
a gate insulation pattern on each of opposite sidewalls in the first direction of one of the plurality of channels; and
a gate electrode on a sidewall in the first direction of the gate insulation pattern;
a contact plug on the one of the plurality of channels;
a landing pad on the contact plug; and
a capacitor including:
a lower capacitor electrode on the landing pad;
a dielectric pattern on a sidewall and an upper surface of the lower capacitor electrode; and
an upper capacitor electrode on a surface of the dielectric pattern,
wherein the capacitor has a lowermost surface lower than an upper surface of the landing pad where an upper surface of one of the plurality of bit lines corresponding to the one of the plurality of channels provides a base reference plane.

17. The semiconductor device of claim 16, further comprising:
a plurality of insulating interlayers between the plurality of bit lines, respectively; and
a plurality of molds on the plurality of insulating interlayers, the plurality of molds contacting sidewalls in the second direction of the plurality of channels;
wherein the gate structure extends in the second direction on the plurality of bit lines and the plurality of insulating interlayers and contacts sidewalls in the first direction of the plurality of channels and the plurality of molds.

18. The semiconductor device of claim 17, further comprising:
a first insulation pattern extending in the second direction on the plurality of bit lines and the plurality of insulating interlayers, the first insulation pattern contacting a sidewall of the gate structure in the first direction; and
a second insulation pattern on the gate structure, the first insulation pattern and the plurality of molds, the second insulation pattern being on a sidewall of the contact plug and a sidewall of a lower portion of the landing pad.

19. The semiconductor device according to claim 18, wherein the dielectric pattern contacts an upper surface of the second insulation pattern.

20. The semiconductor device according to claim 16, wherein sidewalls of the lower capacitor electrode, the landing pad and the contact plug are aligned with each other in the third direction.
